(19) United States
(12) Patent Application Publication
(10) Pub. No.: US 2025/0151503 A1
(43) Pub. Date: May 8, 2025

(54) INTEGRATED LED PACKAGING STRUCTURE AND PACKAGING METHOD

(71) Applicant: JOINTEC OPTOELECTRONICS (ZHEJIANG) CO., LTD, JIAXING (CN)

(72) Inventors: ZHENG JIN, JIAXING (CN); LONGLONG LV, JIAXING (CN); YUNZHI ZHU, JIAXING (CN); CHUNFANG XIAN, JIAXING (CN)

(21) Appl. No.: 19/016,355

(22) Filed: Jan. 10, 2025

Related U.S. Application Data
(63) Continuation of application No. PCT/CN2024/118220, filed on Sep. 11, 2024.

(30) Foreign Application Priority Data
Sep. 12, 2023 (CN) 202311173003.0

(51) Int. Cl. H10H 29/85; H10H 29/01; H10H 29/24; H10H 29/854

(52) U.S. Cl. CPC H10H 29/8585; H10H 29/0362; H10H 29/24; H10H 29/8506; H10H 29/854; H10H 29/857

(57) ABSTRACT

Disclosed are an integrated LED packaging structure and a packaging method, and relates to the technical field of LED packaging. The disclosure includes a shell, a bottom end of the shell is fixedly connected to a pin platform, a top end of the shell is fixedly connected to an LED plug, three lamp beads are fixedly mounted at a top end of the LED plug, a bottom end of the pin platform is fixedly connected to a cup cavity, and a bottom end of the cup cavity is fixedly connected to connecting pins. The top end of the LED plug is provided with LED sockets in positions corresponding to the lamp beads, and bottom ends of inner sides of the LED sockets are fixedly connected to insulating plates. Furthermore, a combination of an in-line and SMD form is adopted, and the lower half part adopts an SMD structure.

### TECHNICAL FIELD

The disclosure relates to the technical field of LED packaging, specifically to, an integrated LED packaging structure and a packaging method.

### BACKGROUND

Packaging of LEDs (semiconductor light-emitting diodes) refers to packaging of light-emitting chips, which is significantly different from packaging of integrated circuits. The packaging of LEDs not only requires protection of wicks, but also requires transparency. Therefore, the packaging of LEDs has special requirements for packaging materials. At present, the conventional LED packaging market is mainly divided into in-line type (lamp type) lamp beads and surface mount device (SMD) lamp beads. The lamp type (also known as DIP in-line type) belongs to the conventional LED packaging mode, which has the advantages of high brightness, high reliability and low failure rate, has the defect of low production efficiency, can only be used for display with large spacing, and is limited in usage scenarios. The SMD (also known as surface mount device) belongs to the conventional LED packaging mode, which has the advantages of large angle, better display effect and high surface mount efficiency, is suitable for display of various sizes, and has the defects of low brightness and poor reliability.

A full-spectrum LED packaging structure with an application number CN202121820373.5 is disclosed in the prior art. An arc-shaped structure of a C type heat conductor is connected to a plano-concave lens, the arc-shaped structure of the C type heat conductor and the plano-concave lens are wrapped with epoxy resin, and transparent balls are mixed inside the epoxy resin, thereby achieving packaging.

However, the prior art still has certain defects. For example, in the technical solution with an application number CN202121820373.5, during use, although it is possible to achieve a certain degree of water tightness by wrapping with epoxy resin, the heat dissipation performance is only reflected by the heat conductor, and the heat conduction performance is limited by the material of the heat conductor, resulting in poor heat conduction effect.

### SUMMARY

In order to solve the defects mentioned in the above background, an objective of the disclosure is to provide an integrated LED packaging structure and a packaging method.

The objective of the disclosure can be achieved through the following technical solution:
Provided is an integrated LED packaging structure, including a shell, where a bottom end of the shell is fixedly connected to a pin platform, a top end of the shell is fixedly connected to an LED plug, three lamp beads are fixedly mounted at a top end of the LED plug, a bottom end of the pin platform is fixedly connected to a cup cavity, and a bottom end of the cup cavity is fixedly connected to connecting pins; and
the top end of the LED plug is provided with LED sockets in positions corresponding to the lamp beads, and bottom ends of inner sides of the LED sockets are fixedly connected to insulating plates.

Further, the bottom end of the pin platform is provided with pin grooves in positions corresponding to the connecting pins, and a top end of the pin platform is fixedly connected to pin connectors.

Further, the bottom end of the cup cavity is provided with pin blocking grooves in positions corresponding to the connecting pins, and the bottom end of the cup cavity is provided with mounting grooves.

Further, a length of the pin platform is 5.5 mm, a width of the pin platform is 4.2 mm, and a height of the pin platform is 0.35 mm.

Further, the three lamp beads emit red, blue, and green light respectively, and a center distance between adjacent lamp beads is 1.63 mm.

Further, a total height is 2.85 mm, and a height of the lamp bead is 0.85 mm.

Provided is a packaging method of an integrated LED packaging structure, including the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell to meet the requirement for improving contrast;
step 3: packaging: mounting the shell and the internal structure after the white internal structure and the outer black shell are produced by injection molding, and using an SMD packaging process for processing;
step 4: manufacturing of lamp beads: using a mold pressing process to manufacture three lamp beads, further increasing product brightness based on the lens principle, and wrapping a side surface with a layer of liquid epoxy resin; and
step 5: sealant filling for sealing: filling a sealant for sealing height positions below the pin platform completely after surface mount for a produced display screen.

The disclosure has the following beneficial effects:

1. In the disclosure, a combination of an in-line type and an SMD form is adopted, and the lower half part adopts an SMD structure, so that the advantages of high surface mount efficiency and suitability for various sizes of display screens are retained. Meanwhile, the bottom adopts a large-area pad pin structure, so that the problem of heat dissipation is effectively solved. Compared with a mode of utilizing a heat dissipation body in the prior art, the existing processing mode can solve the problem of heat dissipation and improve the processing efficiency of heat dissipation.

2. When used, the upper half part of the disclosure adopts an in-line type structure, so that the advantages of high brightness and low failure rate are retained, and the power consumption during use can be further reduced to meet the requirement for energy saving. The entire external structure is fully wrapped with epoxy resin to ensure good air tightness and no risk of water vapor infiltration between the two structures.

### BRIEF DESCRIPTION OF FIGURES

The disclosure is further described below with reference to the accompanying drawings.

FIG. 1 is a schematic diagram of an overall structure of the disclosure;

FIG. 2 is a schematic structural diagram of a pin platform and an LED plug of the disclosure; and

FIG. 3 is a schematic structural diagram of pins of the disclosure.

In the figures: 1, shell; 2, pin platform; 21, pin groove; 22, pin connector; 3, LED plug; 31, LED socket; 32, insulating plate; 4, lamp bead; 5, cup cavity; 51, pin blocking groove; 52, mounting groove; 6, connecting pin.

### DETAILED DESCRIPTION

The technical solutions in the embodiments of the disclosure will be clearly and completely described below with reference to the accompanying drawings in the embodiments of the disclosure. Obviously, the described embodiments are only a part rather than all of the embodiments of the disclosure. Based on the embodiments in the disclosure, all other embodiments obtained by those of ordinary skill in the art without creative efforts fall within the protection scope of the disclosure.

In the description of the disclosure, it should be understood that the orientation or position relationships indicated by terms “opening”, “upper”, “lower”, “thickness”, “top”, “middle”, “length”, “inside”, “periphery”, and the like are intended to facilitate the description of the disclosure and simplify the description only, rather than indicate or imply that the component or element referred to need to have a particular orientation or be constructed and operated in a particular orientation, and therefore cannot be construed as a limitation to the disclosure.

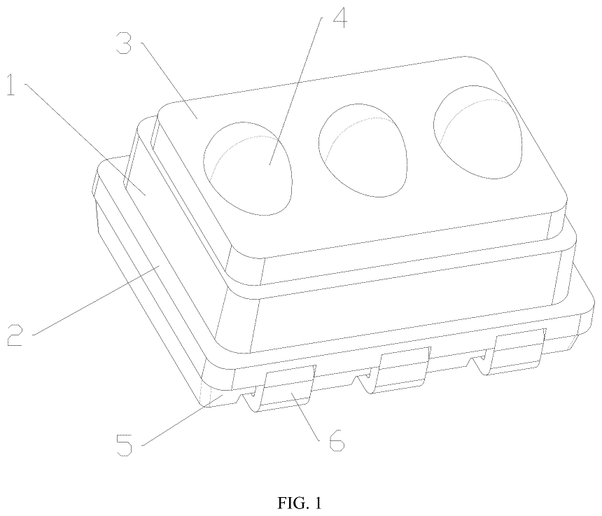

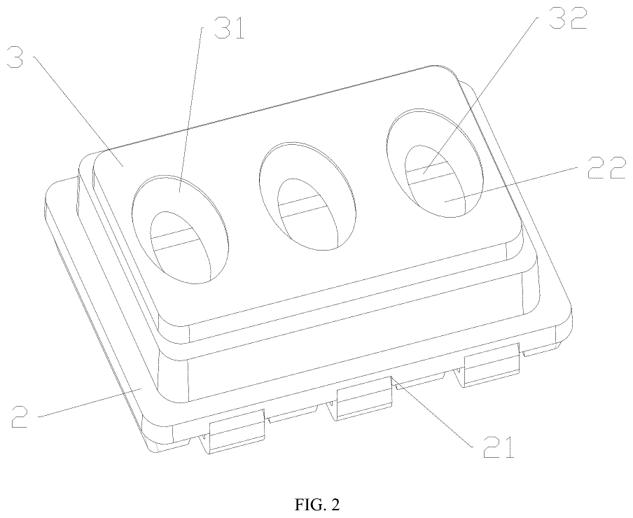

An integrated LED packaging structure and a packaging method are provided. As shown in FIG. 1 and FIG. 2, the integrated LED packaging structure includes a shell 1, a bottom end of the shell 1 is fixedly connected to a pin platform 2, a top end of the shell 1 is fixedly connected to an LED plug 3, three lamp beads 4 are fixedly mounted at a top end of the LED plug 3, a bottom end of the pin platform 2 is fixedly connected to a cup cavity 5, and a bottom end of the cup cavity 5 is fixedly connected to connecting pins 6.

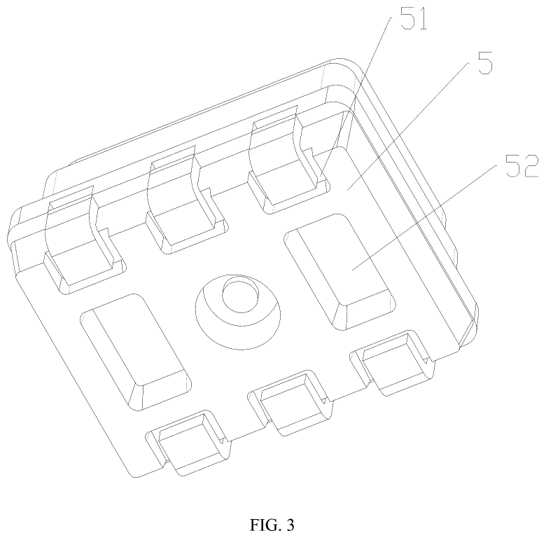

As shown in FIG. 2 and FIG. 3, the bottom end of the pin platform 2 is provided with pin grooves 21 in positions corresponding to the connecting pins 6, and a top end of the pin platform 2 is fixedly connected to pin connectors 22.

The top end of the LED plug 3 is provided with LED sockets 31 in positions corresponding to the lamp beads 4, and bottom ends of inner sides of the LED sockets 31 are fixedly connected to insulating plates 32.

The bottom end of the cup cavity 5 is provided with pin blocking grooves 51 in positions corresponding to the connecting pins 6, and the bottom end of the cup cavity 5 is provided with mounting grooves 52.

A length of the pin platform 2 is 5.5 mm, a width of the pin platform 2 is 4.2 mm, and a height of the pin platform 2 is 0.35 mm.

The three lamp beads 4 emit red, blue, and green light respectively, and a center distance between adjacent lamp beads 4 is 1.63 mm. The distance is also calculated according to data. If the distance is less than this size, the light effects between two colors will affect each other. If the distance is greater than this size, the imaging effect of red, green, and blue primary colors will become poor.

A total height is 2.85 mm, and a height of the lamp bead 4 is 0.85 mm.

This size can be applied to display projects with P8 and larger sizes, and can solve the problems of low brightness and poor reliability of conventional SMD lamp beads in an interval of P8 to P16, as well as the problem of inability to achieve spacing between DIP in-line lamp beads below P16.

When applied outdoors, this size can meet both a sealant filling height of 0.9 mm for the lower half part and a mask thickness of 1.1 mm for the upper half part. All sizes on the product are accurately calculated.

In order to meet the requirements for brightness and contrast, it is generally necessary to adopt a white shell PPA and surrounding ink brushing solution. Although the brightness and contrast meet the requirements, a surface ink layer is easy to fall off, and the phenomenon of uneven ink may occur easily, resulting in poor contrast of the entire display screen.

An all-black PPA solution can obtain better contrast, but a black cup cavity will affect the brightness of a light-emitting chip. The brightness of a final product is very low and cannot meet the daily outdoor display needs. The final product can only be used in special projects with low brightness requirements but high contrast requirements. Both of the above solutions have certain defects.

Provided is a packaging method of an integrated LED packaging structure, including the following steps:
step 1: selection of an injection molding material: a pure white injection molding material is used for injection molding on an internal support structure to meet the brightness requirement of a product;
step 2: selection of an injection molding material: pure black PPA is used for injection molding to produce a set of shell 1 to meet the requirement for improving contrast;
step 3: packaging: the shell 1 and the internal structure are mounted after the white internal structure and the outer black shell 1 are produced by injection molding, and an SMD packaging process is used for processing;
step 4: manufacturing of lamp beads 4: a mold pressing process is used to manufacture three lamp beads 4, product brightness is further increased based on the lens principle, and a side surface is wrapped with a layer of liquid epoxy resin; and
step 5: sealant filling for sealing: a sealant is filled for sealing height positions below the pin platform 2 completely after surface mount for a produced display screen.

After sealant filling for sealing, the entire structure exposed outdoors is made of epoxy resin. Moreover, the epoxy resin is directly bonded to black PPA resin without ink as a middle barrier, so that it is not easy to fall off due to a gap. The reliability of the entire product can reach the level of DIP in-line lamp beads.

In the disclosure, injection molding is performed in two colors, and white PPA is used for injection molding on the inside of the entire product completely, thereby meeting the high brightness requirement of the product. Then, a set of molds is developed on the outside for injection molding of all-black PPA for wrapping, which not only achieves the advantage of high brightness of the original product with ink brushed around, but also meets the advantage of high contrast of the all-black PPA shell.

In the description of this specification, the description of a reference term “an embodiment”, “an example”, “a specific example”, or the like means that a specific feature, structure, material, or characteristic that is described with reference to this embodiment or example is included in at least one embodiment or example of the disclosure. In this specification, the exemplary description of the above term does not necessarily refer to the same embodiment or example. In addition, the described specific feature, structure, material, or characteristic may be combined in a suitable mode in any one or more of the embodiments or examples.

The above displays and describes the basic principle, main features, and advantages of the disclosure. Those skilled in the art should understand that the disclosure is not limited by the above embodiments, and the above embodiments and the description in this specification only illustrate the principle of the disclosure. Without departing from the spirit and scope of the disclosure, the disclosure may also undergo various changes and improvements, and these changes and improvements fall within the scope set forth in the disclosure.

What is claimed is:

1. An integrated LED packaging structure, comprising a shell (1), wherein a bottom end of the shell (1) is fixedly connected to a pin platform (2), a top end of the shell (1) is fixedly connected to an LED plug (3), three lamp beads (4) are fixedly mounted at a top end of the LED plug (3), a bottom end of the pin platform (2) is fixedly connected to a cup cavity (5), and a bottom end of the cup cavity (5) is fixedly connected to connecting pins (6); and
the top end of the LED plug (3) is provided with LED sockets (31) in positions corresponding to the lamp beads (4), and bottom ends of inner sides of the LED sockets (31) are fixedly connected to insulating plates (32).

2. The integrated LED packaging structure according to claim 1, wherein the bottom end of the pin platform (2) is provided with pin grooves (21) in positions corresponding to the connecting pins (6), and a top end of the pin platform (2) is fixedly connected to pin connectors (22).

3. The integrated LED packaging structure according to claim 1, wherein the bottom end of the cup cavity (5) is provided with pin blocking grooves (51) in positions corresponding to the connecting pins (6), and the bottom end of the cup cavity (5) is provided with mounting grooves (52).

4. The integrated LED packaging structure according to claim 1, wherein a length of the pin platform (2) is 5.5 mm, a width of the pin platform (2) is 4.2 mm, and a height of the pin platform (2) is 0.35 mm.

5. The integrated LED packaging structure according to claim 1, wherein the three lamp beads (4) emit red, blue, and green light respectively, and a center distance between adjacent lamp beads (4) is 1.63 mm.

6. The integrated LED packaging structure according to claim 1, wherein a total height of the shell (1), the pin platform (2), the LED plug (3), the lamp bead (4), and the cup cavity (5) is 2.85 mm, and a height of the lamp bead (4) is 0.85 mm.

7. A packaging method of an integrated LED packaging structure, applied to the integrated LED packaging structure according to claim 1, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.

8. A packaging method of an integrated LED packaging structure, applied to the integrated LED packaging structure according to claim 2, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.

9. A packaging method of an integrated LED packaging structure, applied to the integrated LED packaging structure according to claim 3, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.

10. A packaging method of an integrated LED packaging structure, applied to the integrated LED packaging structure according to claim 4, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.

11. A packaging method of an integrated LED packaging structure, applied to the integrated LED packaging structure according to claim 5, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.

12. A packaging method of an integrated LED packaging structure, applied to the integrated LED packaging structure according to claim 6, wherein the packaging method comprises the following steps:
step 1: selection of an injection molding material: using a pure white injection molding material for injection molding on an internal support structure to meet the brightness requirement of a product;
step 2: selection of an injection molding material: using pure black PPA for injection molding to produce a set of shell (1) to meet the requirement for improving contrast;
step 3: packaging: mounting the shell (1) and the internal structure after the white internal structure and the outer black shell (1) are produced by injection molding, and using an SMD packaging process for processing;
step 4: manufacturing of lamp beads (4): using a mold pressing process to manufacture three lamp beads (4), further increasing product brightness based on the lens principle, and wrapping a side surface with a layer of liquid epoxy resin; and
step 5: sealant filling for sealing: filling a sealant for sealing height positions below the pin platform (2) completely after surface mount for a produced display screen.
